(19) United States
(12) Patent Application Publication
(10) Pub. No.: US 2006/0246731 A1
(43) Pub. Date: Nov. 2, 2006

(54) Semiconductor device fabrication method

(75) Inventor: Takanobu Nishida, Fukuyama-shi (JP)

Correspondence Address: HARNESS, DICKEY & PIERCE, P.L.C., P.O. BOX 8910, RESTON, VA, 20195, US

(73) Assignee: Sharp Kabushiki Kaisha

(21) Appl. No.: 11/398,533

(22) Filed: Apr. 6, 2006

(30) Foreign Application Priority Data
Apr. 28, 2005 (JP) 2005-132622

(51) Int. Cl. H01L 21/302; B44C 1/22; C23F 1/00

(52) U.S. Cl. 438/706; 438/710; 216/67

(57) ABSTRACT

The present invention provides a semiconductor device fabrication method comprising the steps of: forming a metal film on a semiconductor substrate; forming a hard mask on the metal film; placing the resultant substrate in a processing chamber; reducing a pressure in the processing chamber to a predetermined degree; and feeding an etching gas into the processing chamber and generating plasma of the etching gas in the processing chamber so that the metal film is patterned with the generated plasma, wherein the etching gas comprises an unsaturated hydrocarbon gas.

### CROSS-REFERENCE TO RELATED APPLICATION

This application is related to Japanese Patent Application No. 2005-132622 filed on Apr. 28, 2005, whose priory is claimed and the disclosure of which is incorporated by reference in its entirety.

### BACKGROUND OF THE INVENTION

1. Field of the Invention

The present invention relates to a semiconductor device fabrication method. The present invention is, in particular, preferably applied to formation of a metal wiring in a semiconductor device.

2. Description of Related Art

A metal wiring in semiconductor devices has been formed by patterning an Al film formed on a substrate, by plasma etching. Typically, the patterning has been carried out with use of a resist mask formed on the Al film.

In recent years, for the purpose of ensuring processing accuracy in patterning required with the progress of miniaturization of semiconductor devices, there has been a demand for a reduction in the thickness of a resist mask. It has been difficult to meet the demand, however, because of a low selective ratio between a resist mask commonly used and an etching gas such as Cl₂ or BCl₃ commonly used in plasma etching of an Al film.

For this reason, a hard mask made of a SiO₂ film or a SiN film have been used in place of a resist mask.

The use of a hard mask, however, has given rise to a new problem of an increase in the amount of side etching of an Al film. The cause is considered as follows. When a resist mask is used, carbon atoms and hydrogen atoms, released from the resist mask during the plasma etching, are attached to the sidewalls of an Al film being etched, to form a polymer, thus forming a protective film. The adoption of a hard mask, however, leads to a loss of a source of carbon atoms and hydrogen atoms, with the result that no protective film is formed on the sidewalls of the Al film.

This problem is addressed by Japanese Unexamined Patent Publication No. 2000-124201, which discloses a technique to prevent side etching by using an etching gas containing a CF-containing gas such as CHF₃ as a source of carbon atoms and hydrogen atoms to form a protective film on the sidewalls of an Al film.

According to experiments carried out by the inventor of the present invention, however, use of the etching gas described in the above publication did not sufficiently prevent side etching of an Al film despite optimization of experiment conditions made based on the descriptions in the publication.

### SUMMARY OF THE INVENTION

The present invention has been made in view of these circumstances, and it is a main object to provide a semiconductor device fabrication method capable of preventing side etching of a metal film and thus forming a wiring with a desirable shape.

The present invention provides a semiconductor device fabrication method comprising the steps of: forming a metal film on a semiconductor substrate; forming a hard mask on the metal film; placing the resultant substrate in a processing chamber; reducing a pressure in the processing chamber to a predetermined degree; and feeding an etching gas into the processing chamber and generating plasma of the etching gas in the processing chamber so that the metal film is patterned with the generated plasma, wherein the etching gas comprises an unsaturated hydrocarbon gas.

The inventor of the present invention has found that use of an etching gas containing an unsaturated hydrocarbon gas during patterning of the metal film by plasma etching with use of a hard mask assists in forming a protective film on the sidewalls of a metal film, and thereby prevents side etching of the metal film so that a wiring with a desirable shape can be formed. The present invention has been invented based on the above finding.

The mechanism is not necessarily clear but it is considered that unsaturated bonds contained in the unsaturated hydrocarbon gas are cleaved during generation of plasma to allow carbon atoms to be supplied sufficiently.

### BRIEF DESCRIPTION OF THE DRAWINGS

FIGS. 1A to 1D are sectional views of a semiconductor device showing steps of a semiconductor device fabrication method according to an embodiment of the present invention;

FIG. 2 is an example of plasma etching apparatus usable in carrying out an embodiment of the present invention; and

FIG. 3 is a view for comparison between an amount of side etching of an example of the present invention and an amount of side etching of a comparative example.

### DESCRIPTION OF THE PREFERRED EMBODIMENTS

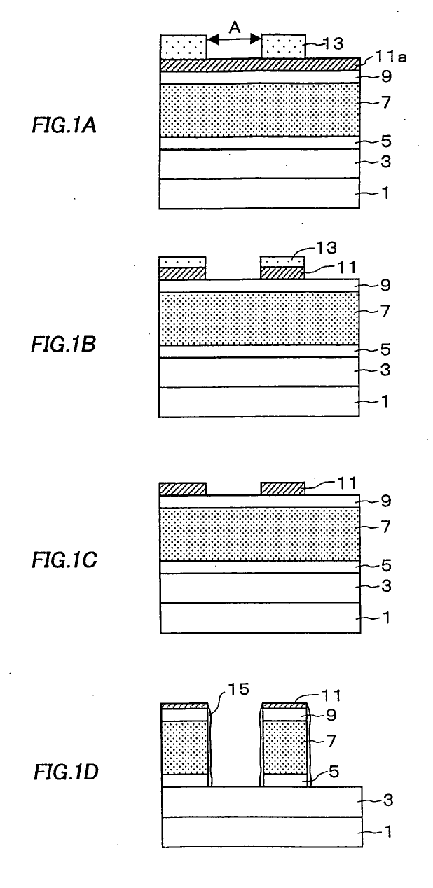

Referring to FIGS. 1A to 1D, there will be explained a semiconductor device fabrication method according to an embodiment of the present invention. FIGS. 1A to 1D are sectional views of a semiconductor device for showing steps of the fabrication method according to the embodiment. Shapes, structures, films and layers thicknesses, compositions, methods and the like shown in the drawing or described in the following text are illustrative only and are not intended to limit the scope of the present invention.

1. Step for Forming Metal Film

First, an interlayer insulating film 3, a barrier film 5 and a metal film 7 are formed in this order on a semiconductor substrate 1, as shown in FIG. 1A.

The material of the semiconductor substrate 1 is not particularly limited, but the semiconductor substrate 1 may be, for example, a Si substrate or a GaAs substrate.

The interlayer insulating film 3 may be, for example, a BPSG film or a SiOF film and formed by CVD or the like. The interlayer insulating film 3 may be formed by coating a polyimide film or the like. The interlayer insulating film 3 is formed to have a thickness of, for example, 400 to 800 nm. The formation method, thickness, composition, constitution (a single layer or a multilayer) of the interlayer insulating film 3 are not particularly limited as long as it can perform a function as an interlayer insulating film.

The barrier film 5 may be, for example, a Ti or Ti/TiN film and formed by sputtering or the like. The barrier film 5 is formed to have a thickness of, for example, 30 to 50 nm. The formation method, thickness, composition and constitution of the barrier film 5 are not particularly limited as long as it can perform a function as a film to prevent the material of the metal film 7 from diffusing into the interlayer insulating film 3.

The metal film 7 is formed of a metal capable of being plasma-etched. Examples of such metals include Al, Al alloys, Ti, TiN, TiW, Ta, TaN, WSi and W. The metal film 7 is preferably formed of Al or an Al alloy in terms of ease of etching. The term “Al alloy” refers to an alloy which contains Al as a main component, such as an alloy containing Si or Cu by several percents with a remainder of Al. The metal film 7 may be a single film or a laminate of a plurality of metal films. The metal film 7 can be formed by vacuum evaporation, sputtering or the like. The metal film 7 is formed to have a thickness of, for example, 150 to 200 nm. The formation method and thickness of the metal film 7 are not particularly limited.

The interlayer insulating film 3 and the barrier film 5 are not essential, and are formed as required.

2. Step for Forming Hard Mask

Next, an anti-reflective film 9 and a film 11a for a hard mask are formed in this order on the metal film 7. The anti-reflective film 9 may be a TiN/Ti film or the like and formed by sputtering or the like. The anti-reflective film 9 is formed to be 40 to 60 nm for example. The anti-reflective film 9 is a film having a function to prevent exposure light from being reflected from the substrate during a photolithography process. The formation method, thickness, composition and constitution of the anti-reflective film 9 are not particularly limited as long as it can perform the above function.

The film 11a for a hard mask may be formed of a material which can ensure a high etching selective ratio to the metal film 7. The film 11a for a hard mask is, for example, formed of an inorganic film such as a silicon dioxide film or a silicon nitride film. The film 11a for a hard mask may be formed by CVD or the like.

Next, a resist layer is formed on the resultant substrate by spin coating and is subjected to photolithography to form a resist mask 13, thereby obtaining the structure shown in FIG. 1A. The resist mask 13 is formed to have a thickness of, for example, 200 to 400 nm. A wiring interval A shown in FIG. 1A is set at, for example, 90 to 130 nm.

Then, the film 11a for a hard mask is patterned by etching with use of the resist mask 13 to form a hard mask 11, thereby obtaining the structure shown in FIG. 1B. After the etching, the resist mask 13 is removed to obtain the structure shown in FIG. 1C. The resist mask 13, however, may be left if it is of a thickness that does not advertently affect a later etching step with use of the hard mask 11.

The hard mask 11 is formed of an inorganic film. The formation method, thickness, composition and constitution of the hard mask 11 are not particularly limited as long as the hard mask 11 can be used for patterning the metal film 7.

The anti-reflective film 9 is not essential, and is formed as required.

3. Step for Patterning Metal Film

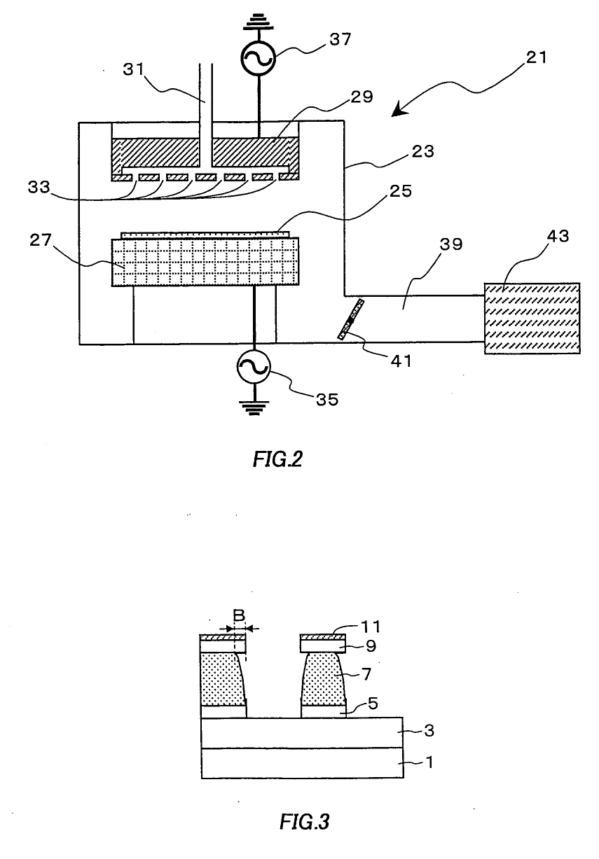

Next, the resultant substrate is placed in a processing chamber of plasma etching apparatus. Referring to FIG. 2, there will be explained an exemplary plasma etching apparatus capable of being used in carrying out the present invention. A plasma etching apparatus 21 is a single-wafer parallel-plate etching equipment. The plasma etching apparatus 21 includes a processing chamber 23 in which a lower electrode 27 on which a substrate 25 to be processed is to be laid and an upper electrode 29 opposed to the lower electrode 27 are provided. The lower electrode 27 is to hold the substrate 25 to be processed, by electrostatic adsorption. A gas introducing port 31 for introducing an etching gas to generate plasma is connected to the upper electrode 29. The upper electrode 29 is formed with a plurality of gas ejecting ports 33 so that the introduced gas can diffuse uniformly to the entire surface of the substrate 25 to be processed. Radio-frequency generator power supplies 35 and 37 which generate different radio-frequencies are connected to the lower electrode 27 and the upper electrode 29, respectively. The processing chamber 23 has at its bottom an exhaust vent 39 with a throttle valve 41 for control of pressure in the processing chamber 23. Air is exhausted by a vacuum pump 43.

Explanations are given referring to FIG. 2, but the method according to the present invention may be carried out with an apparatus other than that shown in the figure, such as plasma etching apparatus of barrel type or microwave-discharge type. Or, the method according to the present invention may be carried out with any apparatus that permits plasma etching.

After the substrate (substrate 25 to be processed) is placed, the pressure in the chamber 23 is reduced. Then, the etching gas is fed into the chamber 23 to generate plasma so that the anti-reflective film 9, the metal film 7 and the barrier film 5 are etched successively with the plasma, thereby obtaining the structure shown in FIG. 1D. During the etching, a protective film of a polymer containing carbon is formed on the metal film 7 sidewalls and the like. The protective film 15 prevents side etching of the metal film 7.

The degree of the pressure reduction is not particularly limited, but preferably the pressure is reduced to a degree suitable for plasma etching.

The etching gas is not particularly limited as long as it permits patterning of the metal film 7 by plasma of the etching gas. Preferably, the etching gas contains a gas that produces a volatile compound by its reaction with the metal film 7, such as a gas containing a chlorine atom. For example, when the metal film 7 is made of Al or an Al alloy, a Cl₂ gas and a BCl₃ gas may be used as the gas containing a chlorine atom.

The etching gas contains an unsaturated hydrocarbon gas. The unsaturated hydrocarbon gas contains one or more unsaturated bonds. The unsaturated bonds are preferably a double bond but may be a triple bond. Both of a double bond and a triple bond may be contained in the unsaturated hydrocarbon gas. Examples of such unsaturated hydrocarbon gases include one in which at least one hydrogen atom has been substituted with a halogen atom such as Cl or F. However, it is preferable that the unsaturated hydrocarbon gas is not substituted since an unsaturated hydrocarbon gas substituted with Cl or F could accelerate the side etching or inhibit the formation of the protective film on the sidewalls.

The number of carbon atoms of the unsaturated hydrocarbon gas is not particularly limited, but preferably 2 to 5. Specifically, the unsaturated hydrocarbon gas may be selected from the group consisting of ethylene, propylene, 1-butene, cis-2-butene, isobutene, trans-2-butene, cis-2-pentene and trans-2-penetene.

The concentration of the unsaturated hydrocarbon gas in the etching gas as a whole is not particularly limited, but is preferably 0.5 to 5%, more preferably 1 to 3%, still more preferably 1.3 to 2%. In such a case, the protective film 15 is effectively formed on the sidewalls and risk of explosion of the unsaturated hydrocarbon gas is riot high.

The unsaturated hydrocarbon gas is preferably diluted with an inert gas such as He, Ne, Ar, Kr or Xe before being fed. In such a case, there is an advantage of a reduction in the risk of explosion of the unsaturated hydrocarbon gas. Dilution ratio of the unsaturated hydrocarbon with the inert gas is not particularly limited but is preferably 37 to 40 (that is, the unsaturated hydrocarbon: the inert gas=1:37 to 40).

Preferable conditions of the plasma etching are as follows. Pressure in the chamber 23: 5 to 15 mTorr; RF power: Ws/Wb=1.59-2.22/0.32-0.45 w/cm², wherein Ws represents radio frequency power to be supplied to the upper electrode 29 and Wb represents radio frequency power to be supplied to the lower electrode 27, ditto for the following; flow rate ratio of the etching gas: Cl₂/BCl₃/C₂H₄(already diluted with the inert gas)/N₂=approximately 0.1-0.3/0.3-0.5/1.0/0.01-0.1; temperature of the lower electrode 27: 20-60° C.; temperature of the sidewalls of the chamber 23: 40-70° C.; temperature of the upper electrode 29: 70-90° C. These conditions are merely for illustration purpose and should not be construed as restricting the present invention. Also, the above conditions of the plasma etching may properly be adjusted according to the kind of the metal film to be processed and according to the size of a wafer to which the present invention is applied.

### EXAMPLE

An example according to the present invention will now be explained referring to FIGS. 1A to 1D. FIGS. 1A to 1D are used merely for convenience of explanation. Film thicknesses and the like described below does not always accurately illustrated in the Figures.

1. Step for Forming Metal Film

First, the interlayer insulating film 3 of BPSG was formed by CVD on the semiconductor substrate (silicon substrate) 1 of a diameter of 200 mm. Then, the barrier film 5 of Ti/TiN and the metal film 7 of an Al alloy (Al: 99.5%, Cu: 0.5%) were formed in this order on the interlayer insulting film 3 by sputtering. The interlayer insulating film 3, the barrier film 5 and the metal film 7 were formed to have thicknesses of 600 nm, 40 nm and 180 nm, respectively.

2. Step for Forming Hard Mask

Next, the anti-reflective film 9 of TiN/Ti and the film 11a of TEOS for a hard mask were formed in this order on the resultant substrate by CVD. The anti-reflective film 9 and the film 11a were formed to have thicknesses of 50 nm and 180 nm, respectively.

Then, the resist film was formed on the resultant substrate by spin coating and was subjected to photolithography to form the resist mask 13, thereby obtaining the structure shown in FIG. 1A. The resist mask 13 is formed to have a thickness of, for example, 300 nm. The wiring interval A was set at, for example, 110 nm.

Then, the film 11a for a hard mask was patterned by etching with use of the resist mask 13 to form the hard mask 11, thereby obtaining the structure shown in shown in 1B. After the etching, the resist mask 13, which had been used in the photolithography, was removed by ashing, thereby obtaining the structure shown in FIG. 1C.

3. Step for Patterning Metal Film

Next, the resultant substrate was placed in the processing chamber (vacuum chamber) 23 of the plasma etching apparatus shown in FIG. 2, and the pressure in the chamber 23 was reduced to 6 mTorr.

Then, an etching gas was fed into the chamber 23 to generate plasma so that the anti-reflective film 9, the metal film 7 and the barrier film 5 are successively etched with the plasma, thereby obtaining the structure shown in FIG. 1D. The flow rate ratio of the etching gas was Cl₂/BCl₃/C₂H₄/N₂=0.2/0.4/1.0/0.05 (The actual flow rates of the gases were Cl₂/BCl₃/C₂H₄/N₂=20/40/100/5 sccm). The RF power was Ws/Wb=1.8/0.38 w/cm². The temperature of the lower electrode 27 was 45° C. The temperature of the sidewalls of the chamber was 65° C. The temperature of the upper electrode 29 was 80° C. C₂H₄ was diluted 37-fold with H₂ in advance, and the above flow rates are based on the diluted gas. Under the above conditions, the concentration of C₂H₄ in the etching gas as a whole is 1.64%.

The amount of side etching, indicated by distance B in FIG. 3, that resulted from the above patterning of the metal film 7, was substantially 0 nm.

### COMPARATIVE EXAMPLE

The metal film 7 was patterned in the same manner as in the above embodiment except that CHF₃ was used in place of C₂H₄. The amount of side etching indicated by distance B in FIG. 3 was about 20 nm. Thus, the effectiveness of the present invention was confirmed.

What is claimed is:

1. A semiconductor device fabrication method comprising the steps of:
forming a metal film on a semiconductor substrate;
forming a hard mask on the metal film;
placing the resultant substrate in a processing chamber;
reducing a pressure in the processing chamber to a predetermined degree; and
feeding an etching gas into the processing chamber and generating plasma of the etching gas in the processing chamber so that the metal film is patterned with the generated plasma,
wherein the etching gas comprises an unsaturated hydrocarbon gas.

2. A semiconductor device fabrication method comprising the steps of:
placing a semiconductor substrate in a processing chamber, the semiconductor substrate having a metal film and a hard mask formed in this order on a surface thereof;
reducing a pressure in the processing chamber;
feeding an etching gas into the processing chamber and generating plasma of the etching gas in the processing chamber so that the metal film is etched with the generated plasma via the hard mask, and thereby is patterned,
wherein the etching gas comprises an unsaturated hydrocarbon gas.

3. The method of claim 1, wherein the unsaturated hydrocarbon gas contains a double bond and 2 to 5 carbon atoms.

4. The method of claim 1, wherein the unsaturated hydrocarbon gas is selected from the group consisting of ethylene, propylene, 1-butene, cis-2-butene, isobutene, trans-2-butene, cis-2-pentene and trans-2-penetene.

5. The method of claim 1, wherein the unsaturated hydrocarbon gas is diluted with an inert gas before being fed.

6. The method of claim 1, wherein the concentration of the unsaturated hydrocarbon gas in the etching gas as a whole is 1.3 to 2%.

7. The method of claim 1, wherein the metal film is an Al film or an Al alloy film.

8. The method of claim 1, wherein the hard mask is formed of a silicon dioxide film or a silicon nitride film.

9. The method of claim 1, wherein the etching gas further comprises a gas containing a chlorine atom.

10. The method of claim 9, wherein the gas containing a chlorine atom comprises a Cl₂ gas and a BCl₃ gas.

11. The method of claim 2, wherein the unsaturated hydrocarbon gas contains a double bond and 2 to 5 carbon atoms.

12. The method of claim 2, wherein the unsaturated hydrocarbon gas is selected from the group consisting of ethylene, propylene, 1-butene, cis-2-butene, isobutene, trans-2-butene, cis-2-pentene and trans-2-penetene.

13. The method of claim 2, wherein the unsaturated hydrocarbon gas is diluted with an inert gas before being fed.

14. The method of claim 2, wherein the concentration of the unsaturated hydrocarbon gas in the etching gas as a whole is 1.3 to 2%.

15. The method of claim 2, wherein the metal film is an Al film or an Al alloy film.

16. The method of claim 2, wherein the hard mask is formed of a silicon dioxide film or a silicon nitride film.

17. The method of claim 2, wherein the etching gas further comprises a gas containing a chlorine atom.

18. The method of claim 17, wherein the gas containing a chlorine atom comprises a Cl₂ gas and a BCl₃ gas.
